(19) United States
(12) Patent Application Publication
(10) Pub. No.: US 2006/0292740 A1
(43) Pub. Date: Dec. 28, 2006

(54) High Temperature Packaging for Electronic Components, Modules and Assemblies

(75) Inventor: Edward Applebaum, La Mirada, CA (US)

Correspondence Address: BROWN RAYSMAN MILLSTEIN FELDER & STEINER, LLP, 1880 CENTURY PARK EAST, 12TH FLOOR, LOS ANGELES, CA, 90067, US

(73) Assignee: SOLID STATE DEVICES, INC., La Mirada, CA (US)

(21) Appl. No.: 11/425,694

(22) Filed: Jun. 21, 2006

Related U.S. Application Data
(60) Provisional application No. 60/693,189, filed on Jun. 22, 2005.

(51) Int. Cl. H01L 21/00; H01L 23/02

(52) U.S. Cl. 438/106; 257/678

(57) ABSTRACT

A high temperature semiconductor packaging, a method for making the same packaging are providing. The packaging comprises a mounting platform, a semiconductor die positioned above the platform and a layer of high temperature passivation coating.

### CROSS-REFERENCE TO RELATED APPLICATIONS

This application claims the benefit of U.S. Provisional Application No. 60/693,189, filed Jun. 22, 2005, which is herein incorporated by reference in its entirety.

### BACKGROUND

The packaging technologies developed for standard silicon semiconductor devices were developed with the inherent silicon properties in mind. As such, current packaging technologies do not permit the SiC (silicon carbide) semiconductor based devices to perform to their full potential. For example, semiconductor devices based upon SiC materials have the unique characteristic of operating at temperatures greater than twice that of standard Si (silicon) based devices. Additionally, semiconductor devices based upon SiC materials also operate very efficiently at very high voltages. What is needed is an entirely new library of techniques, processes, and technologies to maximize the potential of these new semiconductor devices based on SiC materials.

Typically, semiconductor packaging technologies, including advanced packaging applications for military use, are not rated at greater than 175 degree Celsius (175 C) and/or 200 degrees Celsius in extreme enhanced cases. Most importantly, exposure to these temperatures is typically confined to the discrete module elements that do not include assemblies of large functional electronic modules and sub-systems. These assemblies are typically limited to approximately 150 degrees Celsius and below. For this reason, operating temperatures of the heat sinks (base plate) of these modules are limited to approximately 85 degrees Celsius with junction temperature of the semiconductor devices limited to 125 degrees Celsius. What is needed is a method and system for increasing the operating temperature. Additionally, what is needed is a coating to allow for operating at high temperatures.

### SUMMARY

Briefly, and in general terms, various embodiments are directed to high temperature packaging for electronic components, modules and assemblies. In one embodiment, a high temperature semiconductor packaging having a mounting platform is provided. A semiconductor die is positioned above the mounting platform and a layer of high temperature passivation coating is included.

In another embodiment, a method of making a high temperature semiconductor packaging is provided. A mounting plate having a semiconductor die is provided. A high temperature passivation coating is applied and the high temperature passivation coating is then cured.

Other features and advantages will become apparent from the following detailed description, taken in conjunction with the accompanying drawings, which illustrate by way of example, the features of the various embodiments.

### BRIEF DESCRIPTION OF THE DRAWING

FIG. 1 illustrates a top view of an embodiment of a module comprising the high temperature passivation coating.

FIG. 2 illustrates a top view of an embodiment of a module comprising the high temperature passivation coating in a molded form.

FIG. 3 illustrates an embodiment of the high temperature passivation packaging comprising a pre-coated matrix material.

FIG. 4 illustrates an embodiment of the high temperature passivation packaging comprising a coated pre-cut ceramic fabric.

FIG. 5 illustrates an embodiment comprising high temperature passivation coating on a power module.

FIG. 6 illustrates an embodiment of direct application of the high temperature passivation coating.

FIG. 7 illustrates an alternative application embodiment of the high temperature passivation coating.

FIG. 8 illustrates an embodiment of a module utilizing an interface plate.

FIG. 9 illustrates an embodiment of a semiconductor module comprising a thermal substrate acting as a base plate for mounting.

FIG. 10 illustrates an embodiment of a semiconductor module comprising a pressure plate utilized to hold the module substrate onto the heat sink.

### DETAILED DESCRIPTION

Briefly, and in general terms, there is provided high temperature packaging for electronic components, modules and assemblies. More particularly, high temperature packing technologies for silicon carbide (SiC) semiconductor elements are disclosed herein.

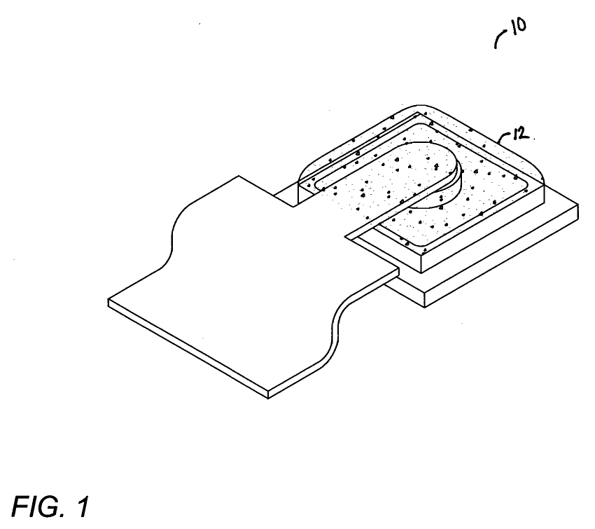

Referring now to the drawings, wherein like reference numerals denote like or corresponding parts throughout the drawings and, more particularly to FIGS. 1-10, there are shown various embodiments various embodiments of high temperature packaging for electronic components, modules and assemblies.

One embodiment includes a new class of semiconductor devices based primarily upon silicon carbide (SiC) materials. The SiC semiconductor devices have many unique characteristics, including, but not limited to, the ability to operate at temperatures greater than twice that of standard silicon (Si) based semiconductor devices. Additionally, the SiC semiconductor devices operate very efficiently at very high voltages. Using SiC in conventional power systems can greatly reduce the size of the power system. In one embodiment, using SiC reduces the conventional power system by about fifty percent. Alternatively, in another embodiment, using SiC reduces the conventional powers system by greater than fifty percent.

In one embodiment, the SiC semiconductor modules, assemblies, and sub-systems are designed to operatively function at higher temperatures. For example, the semiconductor modules, assemblies, and sub-systems are designed to operate at heat sink (base plate) temperatures in excess of 300 degrees Celsius with junction temperatures greater than 375 degrees Celsius. In another embodiment, the SiC semiconductor modules, assemblies, and sub-systems operate continuously at temperatures in excess of 400 degrees Celsius. Optionally, in an alternate embodiment the SiC semiconductor modules, assemblies, and sub-systems operate continuous at temperatures in excess of 400 degrees Celsius.

To operate at these high temperatures, it is necessary to use a suitable dielectric coating. Typically, the dielectric coating is an applied spray or paint that is coated on electronic modules to reduce arc-over at high voltages. High voltage arcing becomes an even greater problem for airborne systems at reduced pressures (e.g. less than ambient pressures) and for systems in outer space.

In one embodiment, an inorganic polymer is used for the dielectric coating. Such inorganic polymers are also called preceramic polymers or preceramic resins. Polysiloxane and polysilazane are two examples of preceramic polymers. Typically, these materials are used to form metal matrix composite alloys, provide coatings for corrosion resistance, and for other primarily mechanical purposes. The preceramic polymer cures at a low temperature and then is converted to a ceramic at higher temperatures. For example, in one embodiment, the preceramic polymer is cured at temperatures ranging from 25 degrees Celsius to about 300 degrees Celsius and is typically converted to a full ceramic at temperatures ranging from about 300 degrees Celsius to about 1400 degrees Celsius.

In one embodiment, the preceramic polymer converts to a full ceramic at temperatures of approximately 800 degrees or higher. Additionally, the assemblies have an upper temperature limitation of approximately 450 degrees Celsius, thereby providing an environment where the preceramic polymer is utilized in a temperature range where it is not fully converted to a ceramic.

As those skilled in the art will appreciate, the dielectric coating may comprise one or more of a number of different materials and/or combinations and hybrids with other organic polymers.

In one embodiment, the dielectric coating is a high temperature passivation coating. In an additional embodiment, the high temperature passivation coating is an inorganic polymer. Optionally, in an alternate embodiment, the high temperature passivation coating comprises a material primarily in the family of polysiloxane and polysilazane resins. Alternatively, in an optional embodiment, the high temperature passivation coating comprises hybrids with organic polymers. As those skilled in the art will appreciate, there are numerous standard and custom formulations may be utilized for the high temperature passivation coating.

The high temperature passivation coating insulates electronic devices, modules, assemblies and systems from high voltage. The high temperature passivation coating is typically cured at temperatures from 25 degrees Celsius (using UV application) to 300 degrees Celsius. After curing, the high temperature passivation coating can then be processed at higher temperatures ranging from about 300 degrees Celsius to about 1400 degrees Celsius. Alternatively, the high temperature passivation coating comprises one or more materials designed to be converted to a full ceramic material when taken to temperatures above 500 degrees Celsius. Optionally, full conversion of the high temperature passivation coating to a ceramic material is not required to obtain the benefits of the material.

In one embodiment, the high temperature passivation coating comprises additional protection properties. Specifically, the high temperature passivation coating assists in protecting the base metals and platings on the electronic devices, modules, assemblies, and systems from the effects of long-term high temperature operations including, but not limited to, oxidation, diffusion, and migration. These are significant problems at temperatures in excess of 300 degrees Celsius, and the use of the high temperature passivation coating can reduce the cost to mitigate these effects.

In another embodiment, the high temperature passivation coating can be altered in composition. Additives (also called “fills”) can be used to enhance and change the final characteristics of the high temperature passivation coating. These additives include ceramic fibers, ceramic powers, ceramic matrices, ceramic fabrics, and other materials typically used with these families of resins.

The high temperature passivation coating may be applied to an individual electronic device as a specific coating. Referring to FIG. 1, a module 10 comprising the high temperature passivation coating 12 is shown. A die 14 is positioned above the mounting platform 16 (cathode interface plate) and comprises a layer of high temperature passivation coating 12. As those skilled in the art will appreciate, the high temperature passivation coating 12 may be applied to the die 14 using numerous application techniques. Such application techniques include, but are not limited to dispensing the coating drop-by-drop, spin coating, spray coating, painting, or other standard industry application techniques. Again, the high temperature passivation coating 12 can vary in composition and have a variety of different additives or fills. As those skilled in the art will appreciate, all derivations of the high temperature passivation coating 12 with one or more additives could be used in any of the application methods described above.

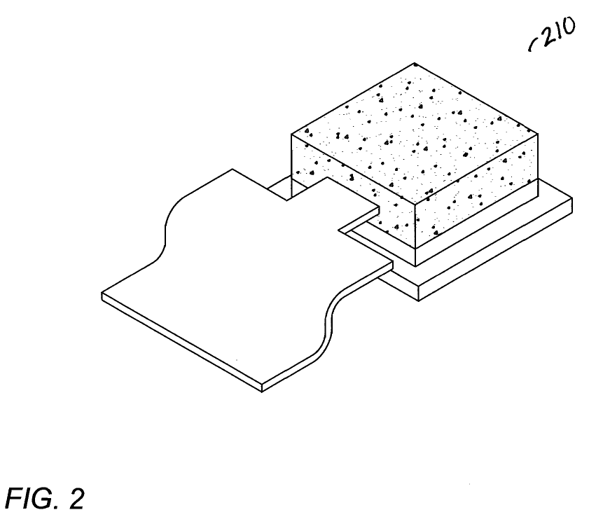

Alternatively, in another embodiment, the high temperature passivation coating 12 may be molded into a predetermined shape or form. Referring to FIG. 2, a module 210 comprising a molded form 212 of the high temperature passivation coating 12 is shown. In one embodiment, the high temperature passivation coating 12 is first applied onto a device or module. The dispensed high temperature passivation coating 12 is then molded into a form, (such as a three-dimensional box) thereby enclosing the critical elements of the device in the high temperature passivation coating 12. In an alternative embodiment, the high temperature passivation coating 12 is first molded into a predetermined form. The molded coating is then placed in a positioned proximate to the die (not shown).

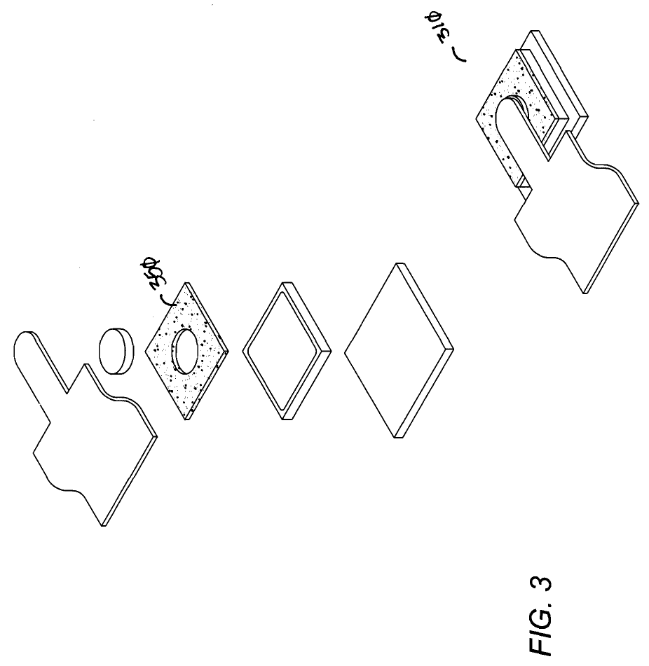

In one embodiment, a matrix of material is pre-coated with the high temperature passivation coating 12 prior to assembly of a module. Referring to FIG. 3, a module 310 comprising a pre-coated matrix of material is shown. Specifically, the module 310 comprises a lead 305, die 314 and a mounting platform 316. A pre-coated matrix of material 350 is positioned above the die 314 in the assembled module 316.

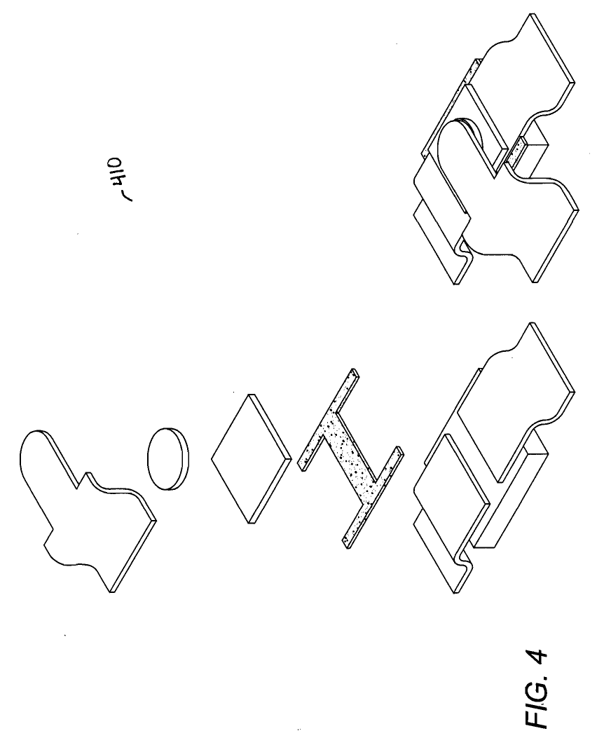

Optionally, in another embodiment, the high temperature passivation coating 12 is first applied to a matrix of ceramic material such as a ceramic fabric that is pre-cut to fit over a device. The resulting coated material may then be assembled during the assembly of the electronic device and cured during this process. This allows greater coverage in hard to apply areas and simplifies the number of assembly steps required. This is especially true for electronic devices bonded in a “flip-chip” manner. An example of this embodiment is illustrated in FIG. 4. Specifically, the high temperature passivation coating 12 is applied to a pre-cut ceramic fabric (not shown) to form the resulting coated material 450. The coated material is then appropriately placed in position during assembly of device 410.

Alternatively, in another embodiment, the above-described device (as illustrated in either of FIGS. 3 and 4) may further be coated or molded with additional resin to further strengthen or provide further coverage.

Optionally, the high temperature passivation coating 12 may also be applied and cured in both the coated and/or matrix form onto the mating substrate of an individual electronic device prior to assembly of the electronic component. Again, this aids in assuring proper coverage of the material in difficult to reach areas.

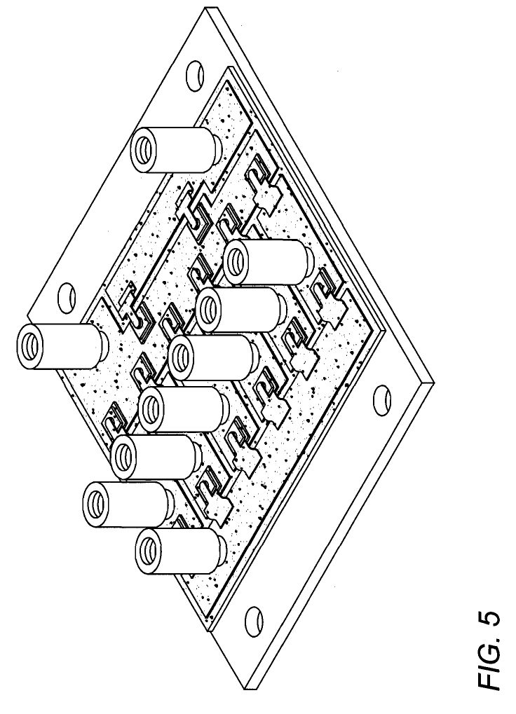

Referring to FIG. 5, the electronic devices must later be mounted together to form a module, assembly, and finally a system. Each level of integration may also include specific coatings that can be applied or formed in the same fashion as those described for the individual electronic component. FIG. 5 illustrates such an embodiment.

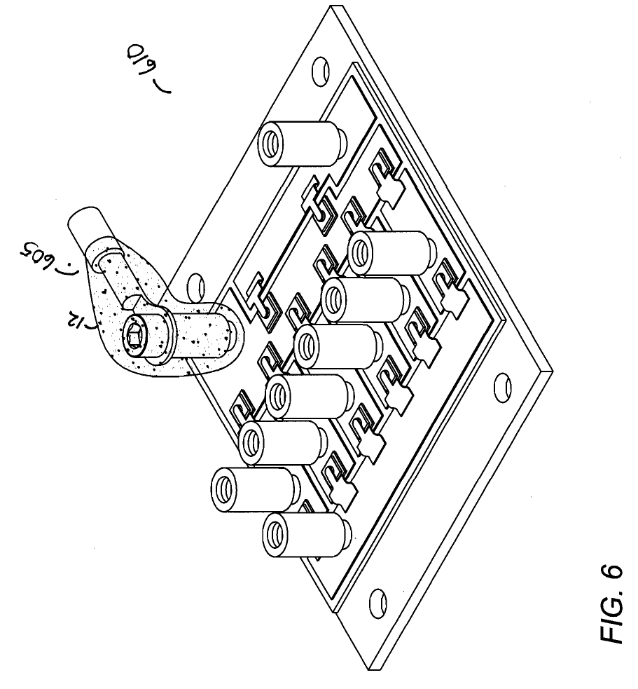

Furthermore, the integration of electrical contacts to and from these modules, assemblies, and systems may also be coated for dielectric and oxidation protection. Again, the similar techniques above may be used to coat these interfaces. Referring to FIG. 6, the high temperature passivation coating 12 may be applied directly onto the component assembly. Specifically, in this example, the high temperature passivation coating has been applied to component 610 of the assembly 605. As those skilled in the art will appreciate, numerous application techniques may be used to apply the high temperature passivation coating. Such techniques include, but are not limited to dispensing the coating drop-by-drop, spin coating, spray coating, painting, or other standard industry application techniques.

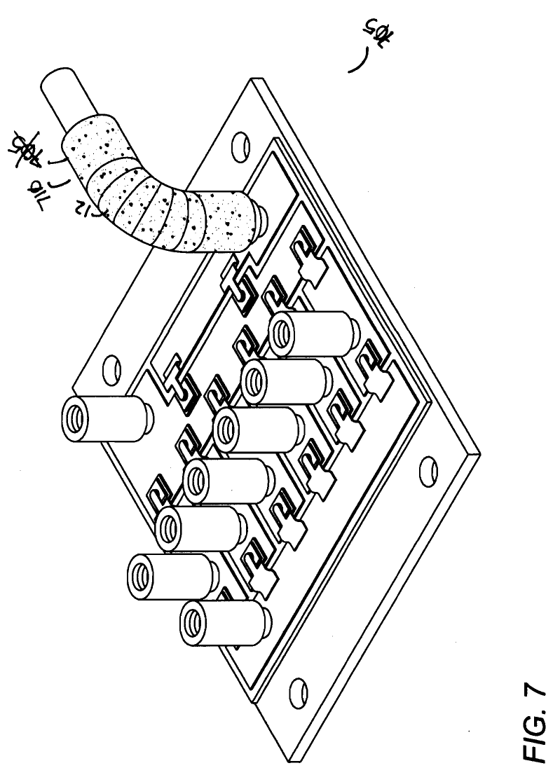

Optionally, a component may be first coated with the high temperature passivation coating and then after coating, the coated component may be cured to the assembled device. Referring now to FIG. 7, a ceramic sleeve 710 is first coated with the high temperature passivation coating 12. The coated sleeve 710 is then cured in place on the terminal interfaces. As noted earlier, this type of application can then be further coated or molded with a preceramic resin for additional strength and protection.

Additionally, another embodiment relates to diffusion bonding processes, and specifically allows the use of standard materials such as AuSn, AuSi, and AuGe alloys (referred to as standard alloys) in environments having a temperature in excess of their standard melting temperature. Specifically, devices utilize plating on the material's surface to alloy during the assembly process with these standard alloys. This first allows a bond to form at standard assembly temperatures. Using a pre-determined temperature and time, the alloys are diffused thereby forming a new alloy having a higher melting temperature. For example, a first device is bonded with a material having a melting point of 280 degrees Celsius at a process temperature of 350 degrees Celsius. The new bonded device forms a new alloy that will not reflow at temperatures over 450 degrees Celsius.

In one embodiment, the above-described process is performed on small individual devices such as a single diode or transistor. However, it can be difficult to control the process for devices having larger areas. For example, the large area substrates used for the next level module assembly can have areas greater that one hundred times the area of the individual die. Typically, a semiconductor module is an array of dies assembled onto a thermal substrate. The thermal substrate is typically attached to a metallic base plate or flange for mounting onto a heat sink. Additionally, very thick and expensive precious metals are used to assist in the diffusion bonding process. This is a significant cost driver to the module cost. One embodiment relates to reducing the cost associated with this type of diffusion bonding process and with overcoming the problems associated with large area substrates. In one embodiment, the standard substrate/base plate configuration is eliminated and thereby eliminating the need for a diffusion bond in this region and reducing manufacturing expenses.

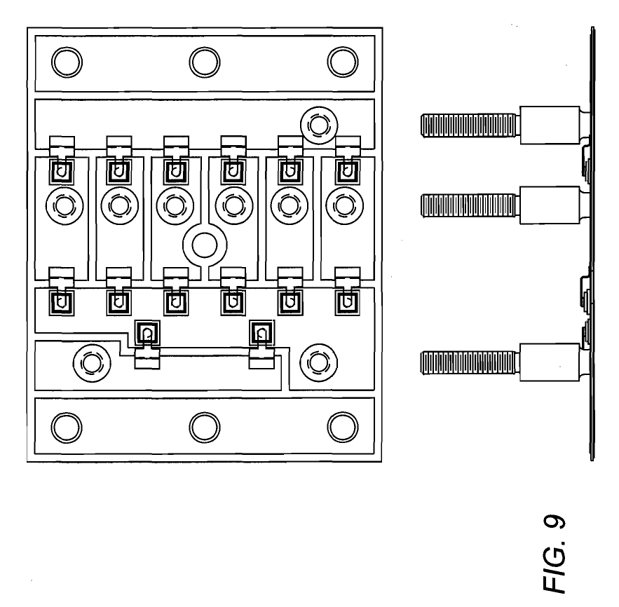

In one embodiment, a semiconductor module 905 comprises an array of dies assembled onto a thermal substrate 910. The thermal substrate 910 is designed such that it is strong enough to act as a base plate for mounting. FIG. 9 illustrates a semiconductor module 905 wherein the conventional base plate has been eliminated. In one embodiment, the substrate comprises a silicon nitride material.

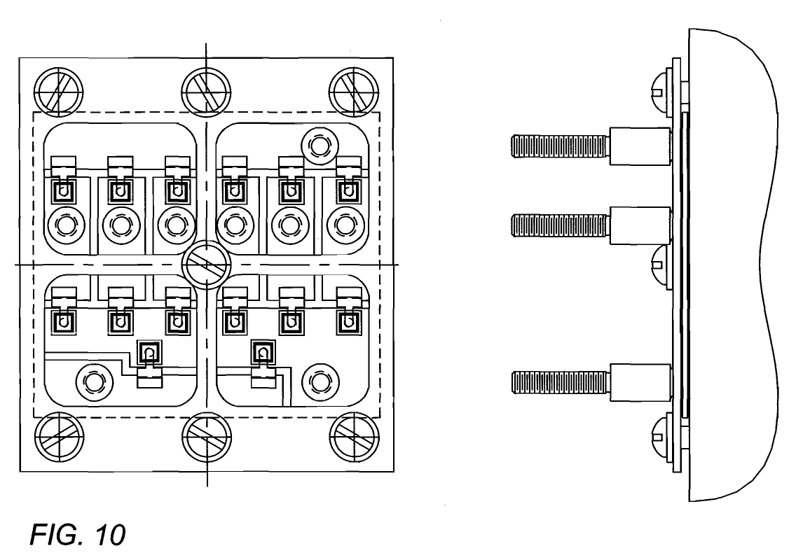

An alternative embodiment related to reducing the cost associated with this type of diffusion bonding process and with overcoming the problems associated with large area substrates is illustrated in FIG. 10. Specifically, in FIG. 10, a pressure plate 1010 is utilized to hold the module substrate 1000 onto the heat sink. The pressure plate is composed of materials suitable for operation at the targeted temperatures in excess of 250 degrees Celsius. In this embodiment, the pressure plate 1010 allows for flexibility in selecting the substrate material. For example, the pressure plate 1010 allows for the selection of a substrate material providing suitable thermal conductivity properties. In one embodiment, a ceramic based material with significant strength to assure proper mounting is used. In another embodiment, SiN is a suitable material for this application. As those skilled in the art will appreciate, other materials may be suitable. Additionally, in another embodiment, the ceramic-based material comprises desirable properties including, but not limited to, thermal expansion, thermal conductivity, availability, low cost, or a combination thereof.

In another embodiment, the pressure plate 1010 comprises a particular geometry and structure designed to sufficiently and evenly apply force to the module substrate 1000 during mounting. Accordingly, the interface between the pressure plate 1010 and module substrate 1000 is designed to assure proper pressure and minimize stress to the substrate.

Since the need to form a diffusion bond between the substrate and base plate has been eliminated, special platings on these surfaces can also be eliminated for the large module design, yielding significant cost savings. However, the top side module surface, may still need special platings for the diffusion process.

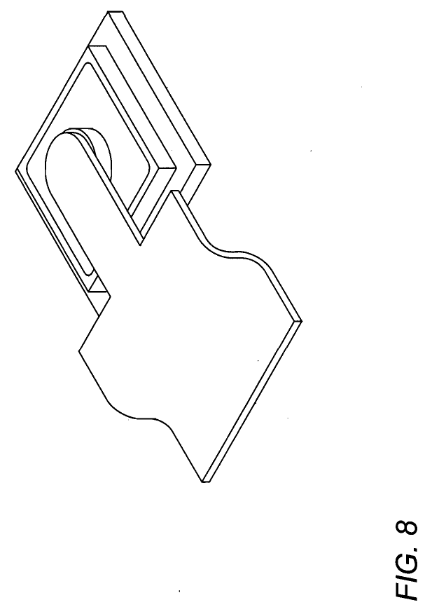

Typically, the diffusion bonding process requires special plating on all surfaces to function properly. The diffusion bonding process can be enhanced to run with only one side enhanced. It is preferable that the die side is not enhanced due to the difficulties of applying the special plating and needing specialized die specifications. This is expensive and limits the availability of die that could be used with this process. Accordingly, in one embodiment, an interface plate is utilized between the die and the substrate. Referring to FIG. 8, a module 800 having an interface plate 820 and die 810 are shown. In one embodiment, the interface plate 820 is approximately the same size as the die 810. Alternatively, in another embodiment, the interface plate 820 is not the same size as the die 810.

By utilizing this interface plate, the special plating can be applied only to the surfaces of this plate. This improves control over the plating process and significantly reduces the plating costs. In one embodiment, the interface plate comprises a material that is matched in expansion to the die such as tungsten, molybdenum, or similar alloys having adequate thermal conductivity. In other embodiments, the interface plate may be made from ceramics, diamonds, or other materials.

The various embodiments described above are provided by way of illustration only and should not be construed to limit the claimed invention. Those skilled in the art will readily recognize various modifications and changes that may be made to the claimed invention without following the example embodiments and applications illustrated and described herein, and without departing from the true spirit and scope of the claimed invention, which is set forth in the following claims.

What is claimed:

1. A high temperature semiconductor packaging, comprising:
a mounting platform;
a semiconductor die positioned above the mounting platform; and
a layer of high temperature passivation coating.

2. The packaging of claim 1 wherein the layer of high temperature passivation coating is applied to the semiconductor die.

3. The packaging of claim 1 wherein the layer of high temperature passivation coating is molded into a predetermined shape.

4. The packaging of claim 1 wherein the layer of high temperature passivation coating pre-applied to a matrix of material.

5. The packaging of claim 1 wherein the high temperature passivation coating is an inorganic coating.

6. The packaging of claim 1 wherein the high temperature passivation coating is a preceramic resin.

7. The packaging of claim 1 wherein the high temperature passivation coating is polysiloxane, polysilazane resin, a hybrid of organic polymers, or a combination thereof.

8. The packaging of claim 1 wherein the semiconductor die is a silicon carbide semiconductor die.

9. The packaging of claim 1 wherein the high temperature passivation coating can be processed at temperatures ranging from about 300 degrees Celsius to about 1400 degrees Celsius.

10. A method of making a high temperature semiconductor packaging, the method comprising:
providing a mounting plate having a semiconductor die;
applying a high temperature passivation coating; and
curing the high temperature passivation coating.

11. The method of claim 10, wherein the high temperature passivation coating is applied directly onto the semiconductor die.

12. The method of claim 10, wherein the high temperature passivation coating is molded into a predetermined shape and then positioned adjacent the semiconductor die.

13. The method of claim 10, wherein applying the high temperature passivation coating further comprises dispensing the coating drop-by-drop, spin coating, spray coating, painting, or other standard industry application techniques.

14. The method of claim 10, further comprising applying the high temperature passivation coating to a ceramic fabric over the mounting plate prior to applying the high temperature passivation coating.

15. The method of claim 10, further comprising applying a resin over the high temperature passivation coating.

16. The method of claim 10, further comprising processing the high temperature passivation coating after curing the coating.
